(19) United States
(12) Patent Application Publication
(10) Pub. No.: US 2012/0250881 A1
(43) Pub. Date: Oct. 4, 2012

(54) MICROPHONE BIASING

(76) Inventor: Daniel P. Mulligan, Austin, TX (US)

(21) Appl. No.: 13/074,303

(22) Filed: Mar. 29, 2011

(51) Int. Cl. H04R 3/00; H03F 3/68

(52) U.S. Cl. 381/92; 330/124 R

(57) ABSTRACT

A plurality of microphones are coupled in series to receive a bias current. A plurality of configurable switches may be used to select which ones of the microphones receive the bias current. The current source may be adjustable and the switches may be reconfigurable to dynamically change both the number of microphones being used and the amount of bias current being generated.

### BACKGROUND

1. Field of the Invention

The invention relates to microphones and more particularly to bias currents used by microphones.

2. Description of the Related Art

Several types of microphones are commonly used in consumer electronics devices such as phones, tablet computers, laptops, etc. The various types of microphones include Electret Condenser Microphones (ECM), MEMs Microphones, and Digital Microphones. The cost difference between an ECM and other microphone types is currently quite considerable—perhaps as much as $0.50 per microphone, which is a significant cost differential considering that consumer devices such as smartphones are likely to include two or more microphones per product.

An exemplary ECM is shown in FIG. 1. The ECM capacitor 101 is formed by a fixed electrode and a movable diaphragm separated by an air gap. Sound waves cause the diaphragm to move, which changes the value of the capacitance and thus the voltage on the gate of the field effect transistor (FET) 103. The ECM requires a bias voltage across the ECM capacitor (generated through leakage from the FET), and current flowing through the FET.

A typical ECM needs a supply voltage of approximately 2.0V (+U in FIG. 1), an external resistor of approximately 2.2 kΩ, and an external capacitor of approximately 1 μF. That yields a bias current in the region of 0.5 mA flowing through the ECM. The external resistor cannot be shared between multiple ECMs. The external capacitor provides DC blocking as the ECM output voltage is a small signal added to a typically approximately 1V bias voltage.

Unfortunately, ECMs suffer from two key problems. First, they need a microphone bias circuit to operate correctly. Second, they produce a very low strength signal which makes them sensitive to electrical and radio frequency (RF) noise interference.

A typical ECM microphone bias circuit 200 is shown in FIG. 2. Unfortunately, the circuit 200 utilizes a lot of power, depending on the supply voltage that is available to the linear regulator 201. Typically, the supply voltage will probably be from an approximately 3.3V supply rail or approximately 3.6V directly from the lithium battery. Thus, the bias circuit will consume about 1.6-1.8 mW of power per ECM (0.5 mA*3.2-3.6V). FIG. 3 illustrates a system with four ECMs 301, 303, 305, and 307, with each ECM receiving its own bias current and coupled to single-ended amplifiers 309. Each single-ended amplifier receives one of the inputs LIN1_L (line in #1 left), LIN1_R (line in #1 right), LIN2_L (line in #2 left), or LIN2_R (line in #2 right).

As shown in FIG. 4, ECMs are frequently used in differential mode, which makes them less susceptible to picking up noise on the signal traces between the ECM and the audio CODEC. FIG. 4 illustrates an ECM microphone bias circuit using a differential configuration. Unfortunately, the bias circuit in FIG. 4 requires an extra pin per differential ECM, as well as an extra external biasing resistor and an extra DC blocking capacitor. The power consumption will be the same as a single-ended ECM microphone circuit.

Improvements in power consumption and pin requirements associated with microphones are desirable.

### SUMMARY

Accordingly, in one embodiment an apparatus is provided that includes a plurality of microphones coupled to receive a bias current in series. The apparatus may further include an integrated circuit including a current source to supply a bias current to a first one of the microphones and wherein a second one of the microphones is coupled to receive the bias current from the first one of the microphones.

In another embodiment a plurality of microphones are configurable to be coupled in series. A current source is coupled to supply a bias current to an input of a configurable one of the microphones and a ground node is coupled to an output of one of the microphones. In an embodiment a plurality of switches are configurable to cause two or more of the microphones to be coupled in series with one of the microphones connected to receive the bias current from the current source and another of the microphones being connected to ground to provide a path for the bias current to flow through the microphones.

In another embodiment a method of operating a plurality of microphones includes providing a bias current to a first input node of a first microphone and providing the bias current to a second input node of a second microphone that is serially connected to an output node of the first microphone.

In another embodiment an apparatus is provided that includes a current source and a plurality of switches to supply one of a plurality of input/output terminals with a bias current from the current source according to configuration of the switches. A plurality of amplifiers are coupled to the input/output terminals to amplify respective voltages present on the input/output terminals.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a high level diagram of an Electret Condenser Microphone (ECM).

FIG. 2 illustrates a typical ECM microphone bias circuit.

FIG. 3 illustrates a system with four ECMs with each ECM receiving its own bias current.

FIG. 4 illustrates an ECM with a differential amplifier.

FIG. 5 illustrates an exemplary embodiment in which the bias current provided by the current generator is shared by four ECMs.

FIG. 6 illustrates an exemplary embodiment in which the DC blocking capacitors are removed and five ECMs are utilized.

FIG. 7 illustrates an exemplary embodiment that keeps the number of ECMs at four and saves a pin as compared to the embodiment of FIG. 6.

FIG. 8 illustrates another embodiment that allows selection of which ECMs are powered up.

FIG. 9 illustrates a high level diagram of a programmable current source.

FIG. 10 illustrates an exemplary embodiment with MEMs microphones.

FIG. 11 illustrates an embodiment that supports ECMs in single-ended and differential modes, and MEMS, as well as a headset microphone, with flexibility as to which pins are used for microphones.

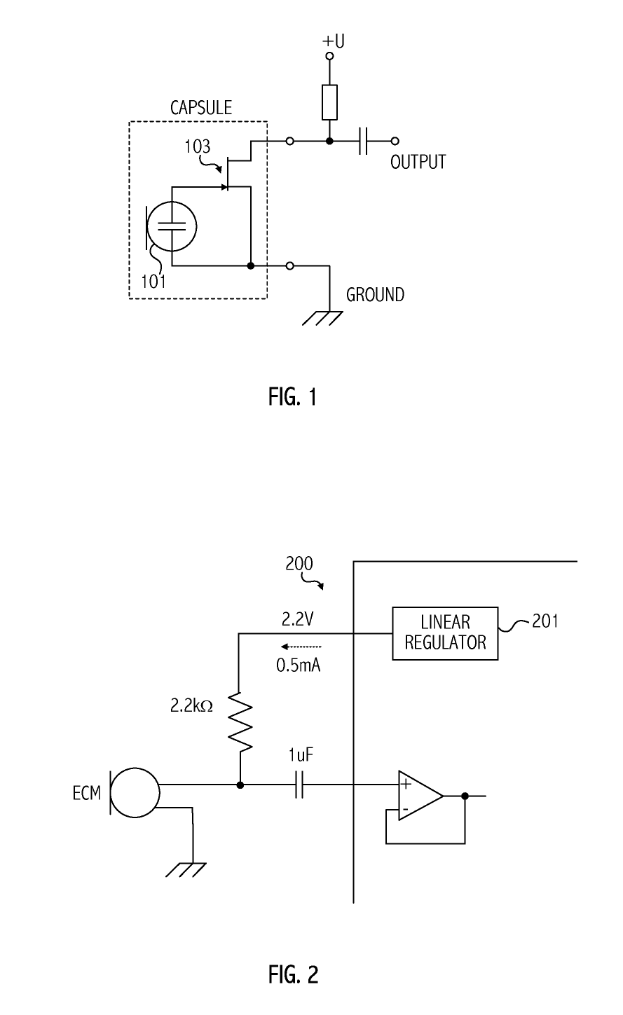

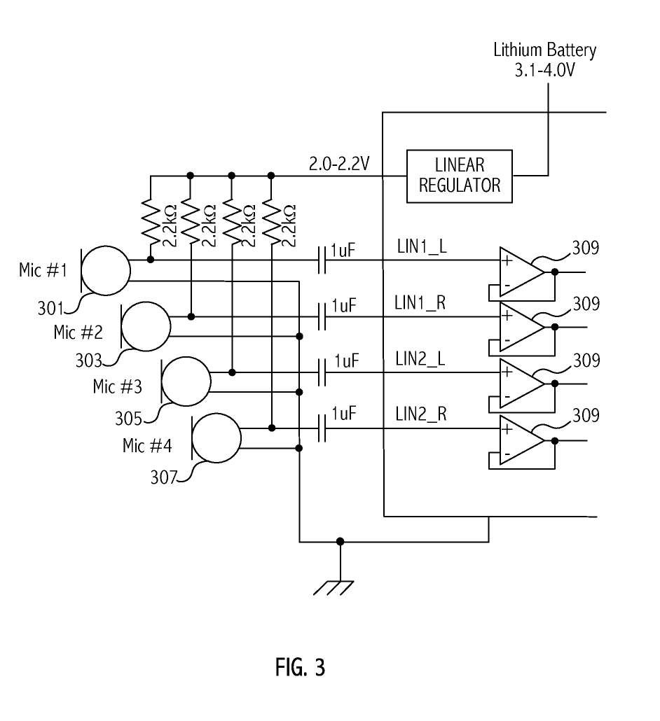

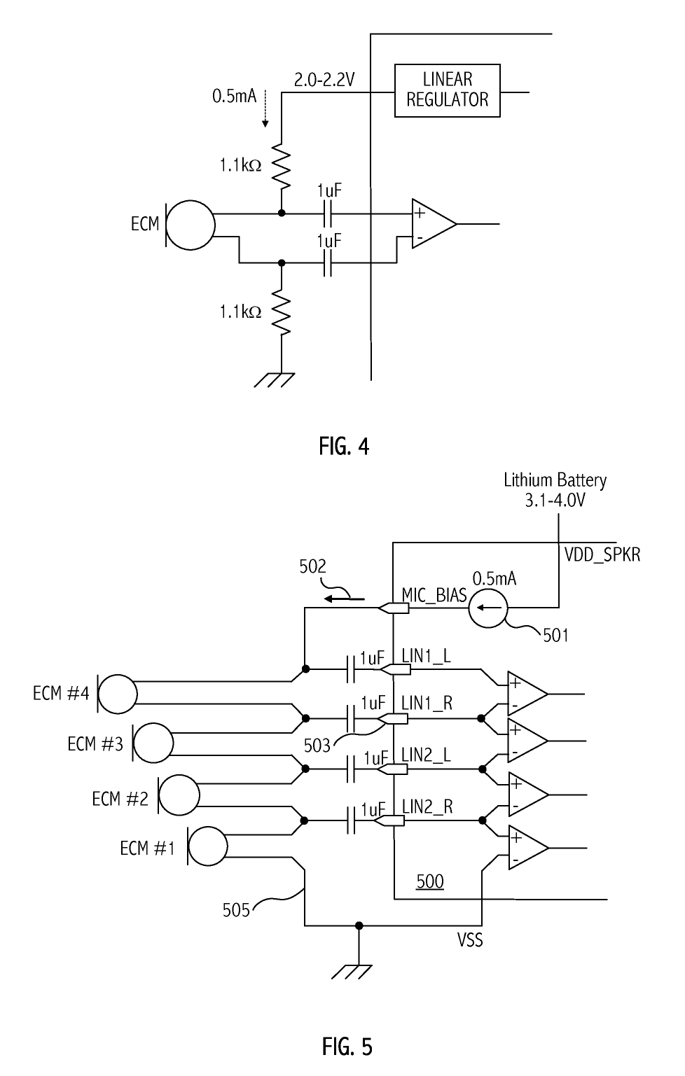

The use of the same reference symbols in different drawings indicates similar or identical items.

### DESCRIPTION OF THE PREFERRED EMBODIMENT(S)

Referring to FIG. 5 illustrated is an exemplary embodiment of the invention. Current generator 501 on integrated circuit 500 provides the bias current 502, which is shared by the four ECMs illustrated. The current flows through each ECM in turn and then to the ground connection at node 505. Another advantage of the embodiment illustrated in FIG. 5 is that it saves pins as compared to the prior art solutions because the ECMs share input/output (I/O) terminals, referred to herein also as pins. Thus, ECM #4 and ECM #3 share the I/O terminal 503. Four pins are saved in the embodiment illustrated in FIG. 5 as compared to the standard way of connecting ECMs in differential mode shown in FIG. 4. The embodiment illustrated in FIG. 5 also reduces the power consumed in biasing the ECMs by a factor of 4 by sharing the bias current.

There are a few compromises in the circuit of FIG. 5, including that a 3.1-4.0V supply available from a lithium battery may not be sufficient to run four ECMs in series. A higher supply voltage, if available, can be used to run four ECMs. Alternatively, one could reduce the number to three ECMs using a supply voltage from a lithium battery, or reduce the bias current to a lower level and run four ECMs from a lithium battery.

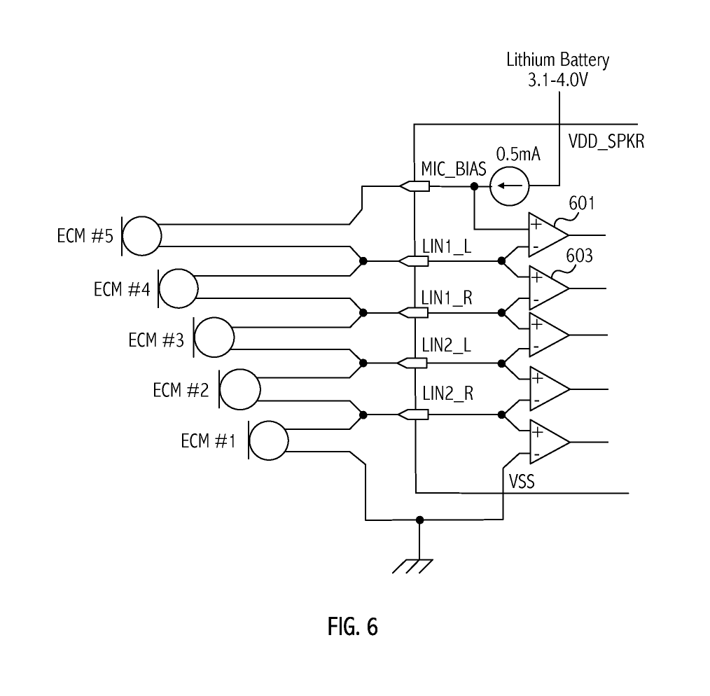

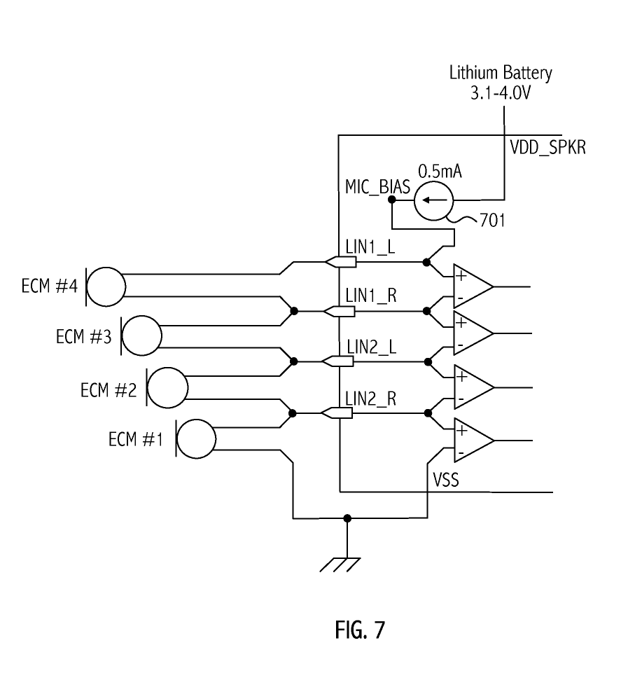

There are several possible improvements that can be made to the circuit of FIG. 5. The first is to eliminate the DC blocking capacitors. Thus, referring to FIG. 6, an embodiment is illustrated in which the DC blocking capacitors are removed. As can be seen in FIG. 6, in addition to eliminating external components (the blocking capacitors), this allows the inclusion of one more ECM with the same number of pins as before. One challenge here will be that some of the input operational amplifiers, e.g., 601 and 603, will have to operate at high voltage points. In addition, the microphone signals may need to be converted from differential to single-ended before being presented to the analog to digital converters (ADCs) for additional processing. Referring to FIG. 7, an alternate approach keeps the number of ECMs at four and saves a pin (five pins instead of six).

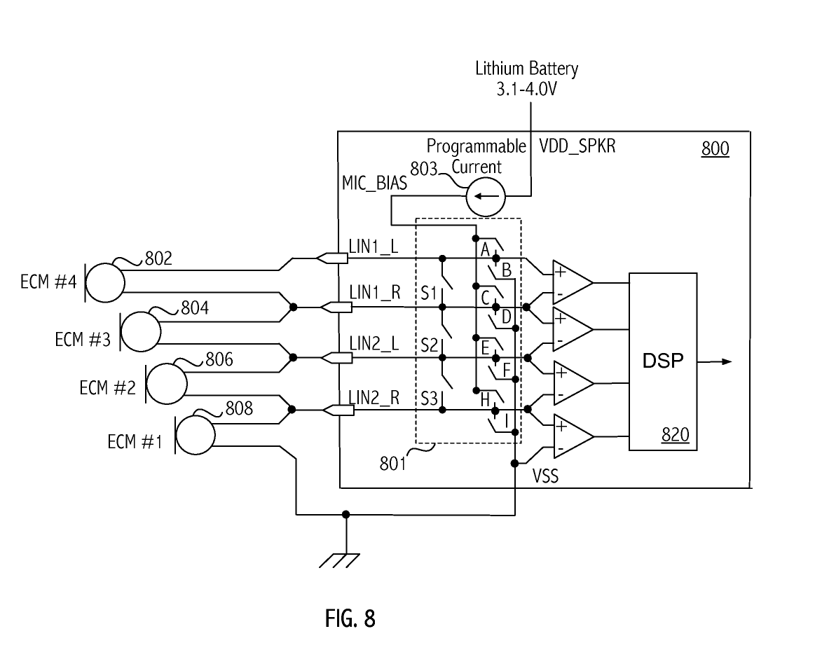

Referring to FIG. 8, another embodiment adds flexibility as to which of the ECMs 802, 804, 806, and 808 are powered up. Integrated circuit 800 includes switches 801 that allow selection of which of the ECMS 802, 804, 806, and 808 are powered up. Thus, e.g., if switch A is closed, and the remaining switches are left open, all the ECMs 802, 804, 806 and 808 are powered up. If switch E is closed and the remaining switches are left open, the ECMs 806 and 808 are powered up. A single ECM may be selected, e.g., ECM 806, by closing switches E and I. Closing switch E supplies the bias current to the upper connector of ECM 806. Closing switch I connects the lower connector of 806 to ground. The purpose of the switches is to allow flexibility. For example, if a system is built without ECMs 802 and 806, then switch S3 is closed to connect ECMs 804 and 808 in series, and switch C is closed to connect the bias current to ECM 804. The switches also provide the flexibility to build a system with all four ECMs, but to only activate some of them, e.g., ECMs 804 and 808, and power down ECMs 802 and 806. The switches can be configured by memory locations on the integrated circuit. The memory may be volatile memory valid only while powered up or non-volatile memory such as a one-time programmable (OTP), or EEPROM. The memory locations may be configurable through a serial port. In embodiments, the switch configurations can be changed dynamically to change the number of ECMs active, as described more fully herein.

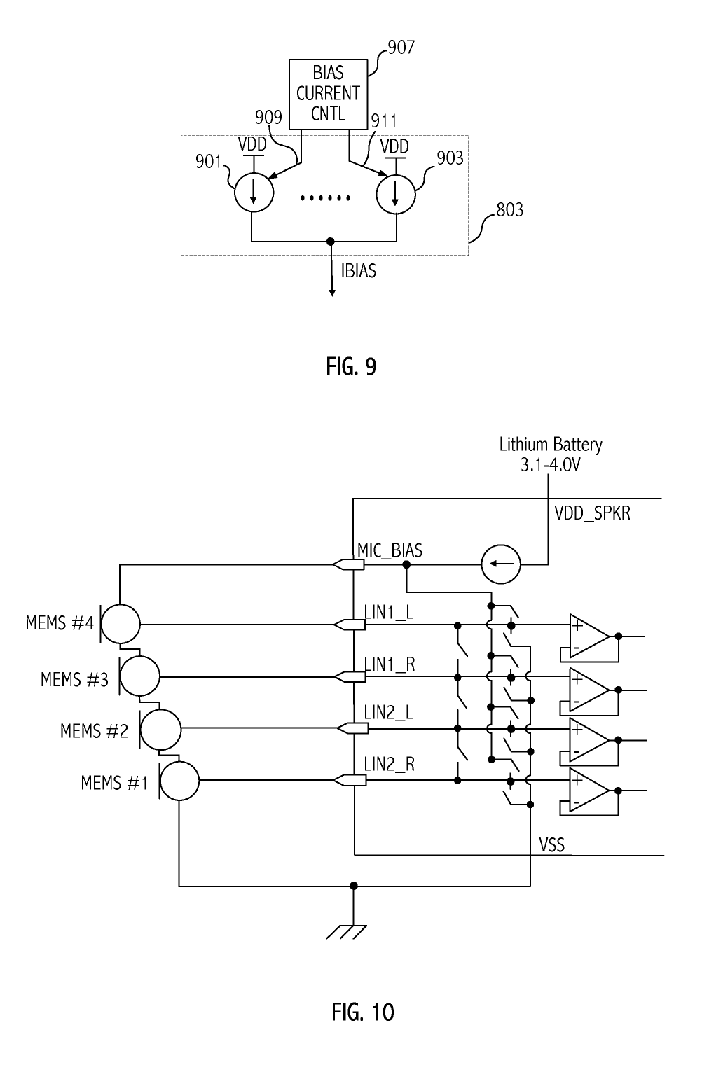

In an embodiment the amount of current supplied by the current source 803 is programmable. Referring to FIG. 9, the bias current controller 907 supplies control signals 909 and 911 to programmable bias current generator 803. The programmable bias current generator may include, e.g., a plurality of individual current sources (only 901 and 903 are shown) that can provide different amounts of current. Control signals 909 and 911 determine if the particular current source is on or off. If the programmable current source 803 is set to provide less current, that would mean lower voltages could be dissipated across each ECM, thereby allowing the use of four ECMs in a system supplied by a lithium battery, at the expense of lower ECM sensitivity and higher noise. Alternatively, the system can provide maximum current and the switches can be set to include only two or three ECMs in the system. The system can trade off power consumption and sensitivity by configuring lower bias current for lower power, and higher bias current for higher sensitivity. Thus, providing the variable bias current capability and the capability to connect a variable number of ECMs allows for dynamically switching between, e.g., four ECMs with low bias current for lower power, and three ECMs with high bias current for higher sensitivity. Alternatively, the system illustrated in FIG. 8 would allow a system that only included one, two, or three ECMs. In such embodiments, with variable bias currents, the switch settings could of course be dynamic as well and allow microphones to be actively switched in and out of use based on the bias current or other criteria. Note that in an embodiment the bias current source can be switched off entirely, thereby eliminating the power consumption associated with the bias current when the ECMs are not in use.

The current source can affect the power supply rejection ratio (PSRR) performance of the microphones. For example, in certain embodiments, the circuit should be able to suppress the 217 Hz power supply ripple present in Global System for Mobile Communication (GSM) technologies. In a GSM system, during a call, the system turns on the transmit power amplifier for a short period at a 217 Hz frequency, which causes a 217 Hz voltage droop on the power supply and is the source of the 217 Hz power supply noise. Of course, other technologies may have different specific PSRR performance requirements.

One benefit of the bias current sharing embodiments described herein is that any power supply ripple that is present in the bias current is spread across multiple ECMs, thereby reducing its magnitude on any one ECM by a factor of up to 4, or 6 dB. Also, the power supply noise on multiple ECMs would be highly correlated with each other, thereby making it significantly easier to suppress in a noise cancellation algorithm running on a digital signal processor (DSP) 820 typically present in the system. Note that other blocks including, e.g., analog to digital conversion (ADC) and storage that may be between the differential amplifiers and the DSP have been omitted in FIG. 8 to simplify the drawing.

In still another embodiment, the microphone bias current is varied dynamically, allowing lower power consumption during periods of silence, and higher sensitivity when noise activity is detected. In such an embodiment the control circuit 907 includes or receives information from a voice activity detect (VAD) circuit (or code running on the DSP) that detects silence or noise. Based on whether there is silence or noise (voice), the control circuit 907 supplies control signals 909 to switch the bias current between a low power standby setting and a high sensitivity setting. Using such a voice detect setting can provide significant power consumption savings compared to a simpler case of using a constant bias current. When switching between no voice and voice, the bias current should be changed smoothly to help reduce the possibility of the bias current change injecting transient noise into the amplified microphone signals.

It may also be desirable to suppress some of the circuit level inaccuracies of this circuit within the DSP. For example, if there are parasitic capacitances on the intermediate nodes between the ECMs, the charging and discharging of these capacitors can be modeled in the DSP and algorithmically subtracted from the signals received at the ADC. Thus, the distortions caused by the serial connections can be corrected algorithmically by digital signal processing.

Referring to FIG. 10, in another embodiment the chaining approach is used with MEMs microphones. The cost savings of using ECMs would be lost, and MEMs typically are not able to be used in differential mode, but the power consumption savings would remain. As before, there might not be enough headroom to power up four MEMS microphones from a lithium battery, and instead, two or three microphones may have to be chained.

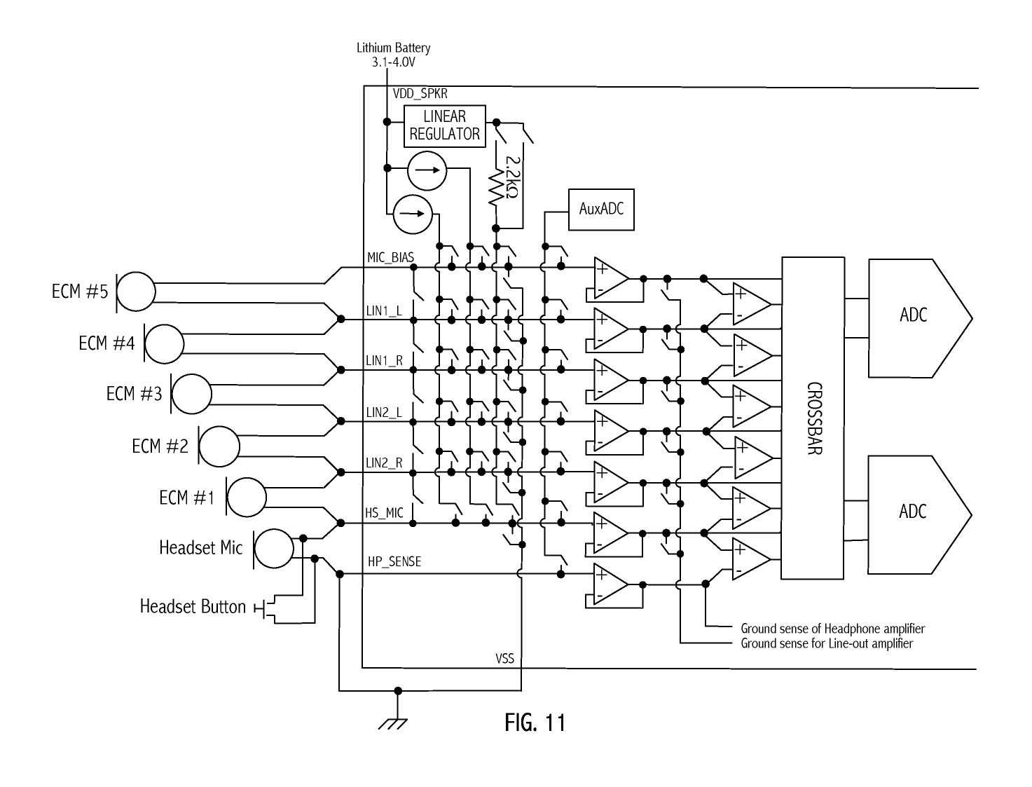

Referring to FIG. 11, another embodiment supports ECMs, in single-ended and differential modes, and MEMS, as well as the headset microphone, with complete flexibility as to which pins are used for microphones. FIG. 11 illustrates all of the different places that the microphones could be placed; however, the number of microphones that may be used at any one time would be limited by the number of channels of ADC conversion that was available in the system.

With smartphones and tablets proliferating in the market place and starting to add additional microphones for noise cancellation, advantages of providing lower power with the additional microphones are significant. Further, applications may utilize many microphones to allow beam forming features, and systems with two, four or more microphones can be expected. Thus, the potential cost savings from using ECMs is multiplied several times and become more important than ever. Absent the chaining embodiments taught herein, the power consumed by the ECMs will be multiplied several times to the point that the ECM biasing circuits could consume as much power as the audio CODEC in a lot of usage modes.

In addition, the best package option for semiconductors targeted at handsets and other consumer electronic products is wafer-level chip scale packages (WL-CSP). WL-CSP allows the smallest size, thinnest die, lowest cost, and highest performance. Unfortunately, the number of pins available in a WL-CSP package is limited by the size of the die. If the required pins are not available in a particular package size, the designer has to either make the die bigger (more cost), or drop pins (reduced functionality). The use of large numbers of ECMs in differential configuration has a good chance of increasing the silicon cost of an audio CODEC. Thus, the reduced pin cost of the embodiments described herein provides significant advantages.

Audio CODEC chips are adding significant amounts of digital processing, which means that they need to be manufactured in more advanced process nodes for best power consumption. More advanced process nodes significantly reduce the die size, which amplifies the WL-CSP pinout pressures. System designers will be faced with the uncomfortable choice between too much cost (because their advanced process audio CODEC die is forced to be bigger to make room for WL-CSP balls) or too much power (because they do not want to pay the cost penalty of going to a more advanced process node where much of the high-cost silicon will be unused). The embodiments described herein help with all of these concerns. Various embodiments described herein save pins (by sharing common nodes between multiple ECM microphones). The various embodiments described herein save power (by sharing bias current between multiple ECM microphones). Use of differential mode for ECMs reduces noise pickup, at the expense of additional pins, while the various embodiments described herein reduce the number of additional pins required for differential mode as compared to prior approaches. The various embodiments described herein can improve PSRR by spreading supply noise across multiple ECMs. Further, embodiments herein potentially save cost by enabling the use of ECMs in situations where they might otherwise not be used.

The description of the invention set forth herein is illustrative, and is not intended to limit the scope of the invention as set forth in the following claims. Other variations and modifications of the embodiments disclosed herein, may be made based on the description set forth herein, without departing from the scope of the invention as set forth in the following claims.

What is claimed is:

1. An apparatus comprising:
a plurality of microphones coupled to receive a bias current in series.

2. The apparatus as recited in claim 1 further comprising an integrated circuit including a current source to supply a bias current to a first one of the microphones and wherein a second one of the microphones is coupled to receive the bias current from the first one of the microphones.

3. The apparatus as recited in claim 1 wherein the integrated circuit includes a plurality of input/output terminals, each of the input/output terminals coupled to a respective two microphones of the plurality of microphones.

4. The apparatus as recited in claim 1,
wherein the integrated circuit includes a plurality of amplifiers coupled to the microphones, and
wherein the amplifiers are differential, each of the amplifiers having a first input coupled to an input node of a respective one of the microphones and a second input coupled to an output node of the respective one of the microphones.

5. The apparatus as recited in claim 1 wherein the microphones are electret condenser microphones (ECMs) or microelectromechanical (MEMS) microphones.

6. The apparatus as recited in claim 1 wherein the current source is programmable to supply a variable amount of current as the bias current according to a control setting.

7. The apparatus as recited in claim 6 wherein the control setting for the current source is adjusted to adjust the bias current according to a detected level of voice activity.

8. An apparatus comprising:
a plurality of microphones configurable to be coupled in series;
a current source coupled to supply a bias current to an input of a configurable one of the microphones; and
a ground node coupled to an output of one of the microphones.

9. The apparatus as recited in claim 8 further comprising:
a plurality of switches configurable to cause two or more of the microphones to be coupled in series with one of the microphones connected to receive the bias current from the current source and another of the microphones being connected to ground to provide a path for the bias current to flow through the microphones.

10. The apparatus as recited in claim 8,
wherein one or more of the plurality of microphones may be bypassed according to configuration of the switches.

11. A method of operating a plurality of microphones comprising:
providing a bias current to a first input node of a first microphone; and
providing the bias current to a second input node of a second microphone that is serially connected to an output node of the first microphone to receive the bias current.

12. The method as recited in claim 11 further comprising:
supplying a first voltage on an input node of the first microphone to a first input of a first differential amplifier and supplying a second voltage on an output node of the first microphone to a second input of the first differential amplifier; and
supplying the second voltage on an input node of the second one of the microphones to a first input of a second differential amplifier and supplying a third voltage on an output node of the second microphone to a second input of the second differential amplifier.

13. The method as recited in claim 11 further comprising varying the bias current according to a control setting of the bias current generator.

14. The method as recited in claim 13 further comprising varying the bias current according to a detected level of voice activity.

15. The method as recited in claim 11 further comprising:
configuring a plurality of switches such that the first and second ones of the microphones are in series.

16. The method as recited in claim 15 further comprising:
reconfiguring the plurality of switches to cause a third microphone to be in series with the first and second microphones.

17. The method as recited in claim 16 further comprising reconfiguring the switches to remove one of the first, second, and third microphones from being in series.

18. The method as recited in claim 11 further comprising changing a number of microphones coupled in series to receive the bias current and adjusting an amount of the bias current.

19. The method as recited in claim 11 further comprising suppressing circuit distortions in microphone output caused by serial connecting the bias current using digital signal processing.

20. An apparatus comprising:
a current source;
a plurality of switches to supply one of a plurality of input/output terminals with a bias current from the current source according to configuration of the switches; and
a plurality of amplifiers coupled to the plurality of terminals to amplify respective voltages present on the input/output terminals.

21. The apparatus as recited in claim 20 further comprising:
a plurality of microphones coupled to the input/output terminals and coupled in series so that the bias current flows through the plurality of microphones.
